(19) United States
(12) Patent Application Publication
(10) Pub. No.: US 2020/0135693 A1
(43) Pub. Date: Apr. 30, 2020

(54) SEMICONDUCTOR PACKAGE STRUCTURE AND METHOD OF MAKING THE SAME

(71) Applicant: Phoenix Pioneer Technology Co., Ltd., Hsinchu County (TW)

(72) Inventors: Chu-Chin Hu, Hsinchu County (TW); Shih-Ping Hsu, Hsinchu County (TW); Che-Wei Hsu, Hsinchu County (TW)

(21) Appl. No.: 16/659,716

(22) Filed: Oct. 22, 2019

(30) Foreign Application Priority Data
Oct. 26, 2018 (TW) 107137896

(51) Int. Cl. H01L 25/065; H01L 23/538; H01L 23/00; H01L 23/31; H01L 23/367; H01L 25/00; H01L 21/56; H01L 21/48

(52) U.S. Cl. CPC H01L 25/0652; H01L 23/5383; H01L 24/16; H01L 23/5386; H01L 2224/16227; H01L 23/367; H01L 25/50; H01L 21/563; H01L 21/4853; H01L 23/3128

(57) ABSTRACT

A semiconductor package structure includes a circuit build-up substrate, a chip, a plurality of conductive pillar, a molding layer and at least a memory module. The circuit build-up substrate has a first surface. A plurality of flip-chip bonding pads and a plurality of first bonding pads are exposed from the first surface. The chip is electrically connected to the flip-chip bonding pads. The conductive pillars are disposed on the first surface of the circuit build-up substrate and electrically connected to the first bonding pads. The molding layer is disposed on the first surface of the circuit build-up substrate to cover the chip and the conductive pillars. A second side of the chip and a first end of each conductive pillar are exposed from the molding layer. The memory module is disposed on the molding layer and electrically connected to the first end of the conductive pillar.

### CROSS REFERENCE TO RELATED APPLICATIONS

This Non-provisional application claims priority under 35 U.S.C. § 119(a) on Patent Application No. 107137896 filed in Republic of China on Oct.26, 2018, the entire contents of which are hereby incorporated by reference.

### BACKGROUND

### 1. Technical Field

The present invention generally relates to a package structure and its manufacturing method, and more particularly, to a stacked package on package type semiconductor package and method of making the same.

### 2. Description of Related Art

Chip package is mainly used for the protection of integrated circuit, heat dissipation and circuit conduction, etc. With the development of wafer process technology, the performance request like integrated circuit density, transmission rate and signal interference reduction is increasing, which enhance the technical requirement of the integrated circuit chip package gradually.

To centralize several components into one package, a stacked PoP technology was developed, which was to integrate high-density digital or mixed signal logic module in the bottom layer (base) package and high-density or combined memory in the top layer (stack) package for two or more components in the way of vertical stacking or back carrying. Compared with the traditional side-by-side package, stack PoP occupies less PCB surface and simplifies PCB design, which can improve the frequency efficiency through the direct connection between the memory and logic circuit.

As the technology evolved, a kind of fan-out wafer-level package technology, or called as integrated fan-out technology, was also developed, with the advantage of lower cost than traditional PoP package due to no need of substrate, which greatly saved the cost of chip package and can be applied to the large application markets like the processor chip of the mobile communication devices, or other radio frequency and and power management integrated circuit.

As shown from FIGS. 1A to 1K, a conventional manufacturing method of the integrated fan-out package 10 includes the following steps: step S01 is to place a chip 11 on a glass substrate 12 as FIG. 1A; step S02 is to form a molding layer 13 on the glass substrate 12 and the chip 11 to cover the chip 11 as FIG. 1B; step S03 is to make a plurality of openings 131 on the molding layer 13 as FIG. 1C; step S04 is to form conductive pillars 14 in the openings 131 as FIG. 1D; step 05 is to dispose a substrate 15 on the molding layer 13 and the conductive pillars 14 as FIG. 1E; and step S06 is to remove the glass substrate 12 to form a semi-finished semiconductor package 10a as FIG. 1F, and flip the semi-finished semiconductor package 10a so that one active surface 111 of the chip 11 will face up.

And in FIG. 1G, step S07 is to form a redistribution layer 16 on the semi-finished semiconductor package 10a, the following sub-steps will be performed based on the number of the layers required: form the dielectric layer and make an opening on it, then form a metal layer inside the opening, and finally grind the top surface. As shown in FIG. 1G, there are totally ten metal layers in the redistribution layer 16, which means the above sub-steps should be repeated ten times, and the metal layer exposed to the topmost surface will be taken as the connection bonding pad 161.

Step S08 is to form the conductive bump 17a on the connection bonding pad 161 as FIG. 1H; step S09 is to remove the substrate 15 to expose one end of the conductive pillars 14 as FIG. 1I; step 10 is to provide a memory module 18 and electrically connect it to the conductive pillars 14 by the conductive bump 17b as FIG. 1J; and finally step S11 is to form the dielectric layer 19 in the space around the conductive bump 17b to complete the integrated fan-out package 10 as FIG. 1K.

From above, the conventional integrated fan-out package has the following disadvantages: (1) the chip cannot be exposed, so the thermal energy is covered and cannot be dissipated; (2) the redistribution layer is fabricated on the semi-finished product of the semiconductor package after the chip is disposed; if there is defective product due to the fault in the process of making the redistribution layer, the chip may be scrapped accordingly or reworked laboriously.

### SUMMARY OF THE INVENTION

In view of the above, one of the purposes of the invention is to provide a semiconductor package structure and its manufacturing method, which can increase the heat dissipation capacity of the chip and avoid the burial type loss of the chip caused by the yield problem of the conductive circuit.

Another purpose of the invention is to provide a semiconductor package structure and its manufacturing method, which can optimize the process and package structure so as to modularize the memory independently. Therefore, only memory modules with abnormalities need be reworked and replaced without completely scrapping the whole package, which will save the time and cost of the reworking.

To achieve the above, the invention provides a semiconductor package structure, including a circuit build-up substrate, a chip, a plurality of conductive pillars, a molding layer and at least a memory module. The circuit build-up substrate has opposite a first surface and a second surface, with the first surface exposing a plurality of flip-chip bonding pads and a plurality of first bonding pads, and the second surface exposing a plurality of second bonding pads. The chip has opposite a first surface and a second surface, with the former facing the first surface of the circuit build-up substrate and electrically connected to such flip-chip bonding pads. Each conductive pillar has opposite a first end and a second end, with the second end arranged on the first surface of the circuit build-up substrate and electrically connected to the corresponding first bonding pads. The molding layer is arranged on the first surface of the circuit build-up substrate to cover the chip and the conductive pillars, with the second surface of the chip and the first end of the conductive pillars exposed from the molding layer. The memory module is disposed on the molding layer and electrically connected to the first end of the conductive pillars. Additionally, the memory module and the chip do not overlap in an orthographic projection direction so that the chip can be directly exposed for better heat dissipation.

In one embodiment, the semiconductor package structure further includes a conductive adhesive layer, which is arranged between the second end of the conductive pillars and the first bonding pads.

In one embodiment, the semiconductor package structure further includes a heat dissipation component, which is disposed on the memory module or on the second surface of the chip.

In one embodiment, the semiconductor package structure further includes a heat dissipation component, which is disposed on the second surface of the chip.

In one embodiment, wherein the circuit build-up substrate has at least one circuit build-up structure that has a conductor layer, a conductive pillars layer and a dielectric layer, with the conductor layer and the conductive pillars layer overlapping each other and embedded in the dielectric layer.

In one embodiment, the first bonding pads of the circuit build-up substrate are located around the flip-chip bonding pads.

In addition, for the purpose above, the invention provides a manufacturing method for a semiconductor package structure, which includes the following steps: providing a circuit build-up substrate, which has a first surface that exposes a plurality of flip-chip bonding pads and a plurality of first bonding pads located around such flip-chip bonding pads; forming a conductive substrate embedded with a chip and a plurality of conductive pillars on the first surface of the circuit build-up substrate, in which the first surface the chip is disposed corresponding to such flip-chip bonding pads and the second end of the conductive pillars is disposed corresponding to such the first bonding pads; one second surface of the chip and one first end of each conductive pillars are exposed from one upper surface of the conductive substrates; and arranging at least one memory module on the conductive substrate, corresponding to the first end of such conductive pillars, wherein the memory module and the chip do not overlap in an orthographic projection direction.

In one embodiment, the step of forming the conductive substrate embedded with a chip and such conductive pillars includes arranging such conductive pillars on the first surface of the circuit build-up substrate with its second end corresponding to the first bonding pads; disposing the chip on the first surface of the circuit build-up substrate with its first surface corresponding to such flip-chip bonding pads; and forming a molding layer on the first surface of the circuit build-up substrate to cover the conductive pillars and chips as well as expose the first end of each conductive pillars and the second surface of the chip.

In one embodiment, each conductive pillars is a conductive cylinder (e.g. a copper cylinder), which is electrically connected to the corresponding first bonding pads by a conductive adhesive layer at the second end.

In one embodiment, the step of arranging such conductive pillars even include forming a patterned photoresistive layer on the first surface of the circuit build-up substrate and a plurality of blind holes to expose such first bonding pads; making a metal layer on such blind holes and exposing from such first bonding pads; and removing the patterned photoresistive layer to form such conductive pillars and expose such flip-chip bonding pads.

In one embodiment, wherein the step of forming a conductive substrate embedded with the chip and such conductive pillars is to dispose the chip on the first surface of the circuit build-up substrate with its first surface corresponding to such flip-chip bonding pads; form a molding layer on the first surface of the circuit build-up substrate to cover the chip; make a plurality of openings on the molding layer which are corresponding to the first bonding pads and form a plurality of conductive pillars in the openings that are electrically connected to the corresponding first bonding pads; and expose a first end of such conductive pillars and a second surface of such chip from the molding layer.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

The parts in the drawings are not necessarily drawn to scale, the emphasis instead being placed upon clearly illustrating the principles of at least one embodiment. In the drawings, like reference numerals designate corresponding parts throughout the various diagrams, and all the diagrams are schematic.

FIGS. 1A to 1K are schematic diagrams showing the procedure for making an integrated fan-out package.

FIGS. 2A to 2F are schematic diagrams showing the procedure for making a semiconductor structure according to the first embodiment of the invention.

FIG. 3 is a top view of the semiconductor structure according to the first embodiment of the invention.

FIG. 3-1 is a top view of the semiconductor structure according to another embodiment of the invention.

FIGS. 4A to 4G are schematic diagrams showing the procedure for making a semiconductor structure according to the second embodiment of the invention.

FIGS. 5A to 5D are schematic diagrams showing the procedure for making a semiconductor structure according to the third embodiment of the invention.

### DETAILED DESCRIPTION

Reference will now be made to the drawings to describe various inventive embodiments of the present disclosure in detail, wherein like numerals refer to like elements throughout.

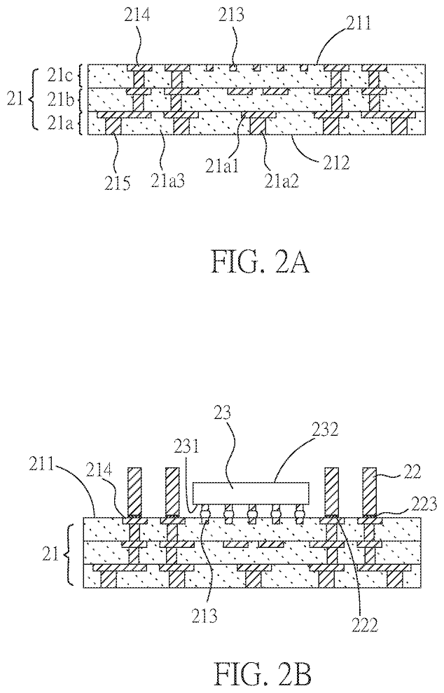

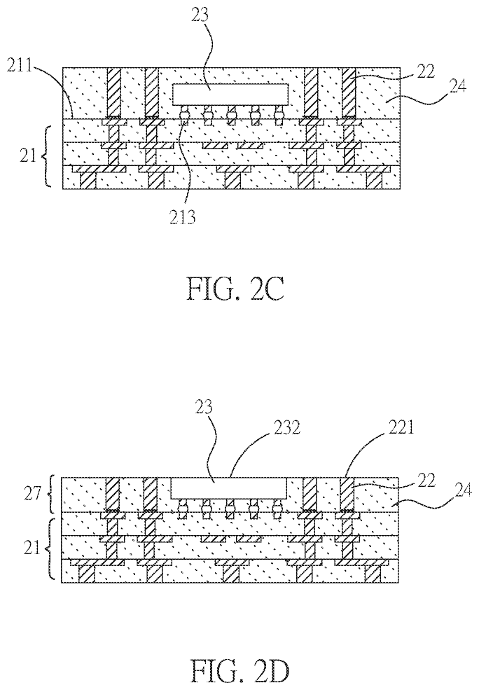

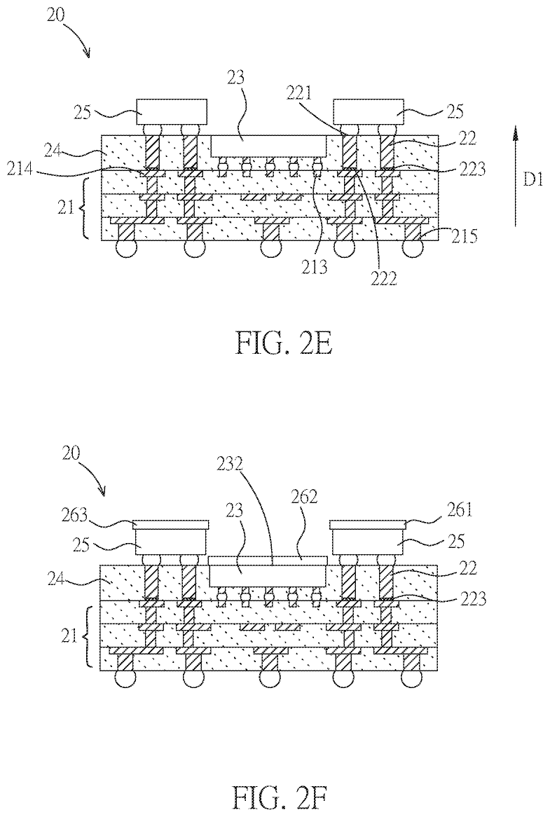

Please refer to FIGS. 2A to 2F to illustrate the manufacturing method of the semiconductor package structure 20 of the first embodiment in the invention from step S21 to S28.

Step S21 is to provide a circuit build-up substrate 21 as shown in FIG. 2A, which has a first surface 211 and a second surface 212, with a plurality of flip-chip bonding pads 213 and a plurality of the first bonding pads 214 exposed on the first surface 211, and a plurality of the second bonding pads 215 on the second surface 212. Among them, such first bonding pads 214 of the circuit build-up substrate 21 are located around such flip-chip bonding pads 213.

In the embodiment, the circuit build-up substrate 21 has the circuit build-up structure 21a, 21b and 21c. The circuit build-up structure 21a has a conductor layer 21a1, a conductive pillars layer 21a2 and a dielectric layer 21a3. The conductor layer 21a1 and the conductive pillars layer 21a2 are overlapping, and electrically connected and embedded in the dielectric layer 21a3.

The conductor layer 21a1 and conductive pillars layer 21a2 may include conductive metal materials such as copper, silver, nickel or alloys of their composition. Microlithography technology can be used to perform the procedure of exposure and development with additional photoresistive layer (not shown in the figure) and the procedure of electroplating to complete the process.

Moreover, the circuit build-up structure 21b and 21C can be configured similar to the circuit build-up structure 21a and accomplished by the microlithography and metal plating technology, which will not be discussed here. It is worth mentioning that the exposed conductor layer or conductive pillars layer in the circuit build-up structure can become the flip-chip bonding pads 213, the first bonding pads 214 and the second bonding pads 215, respectively.

Step S22 is to dispose a plurality of conductive pillars 22 made of copper on the first surface 211 of the circuit build-up substrate 21 with its second end 222 corresponding to the first bonding pads 214 as shown in FIG. 2B. In the embodiment, the conductive pillars 22 is formed at first, and then disposed on and electrically connected to the corresponding first bonding pads 214 by means of the conductive adhesive layer 223 like conductive resin at its second end 222.

Step S23 is to dispose a chip 23 on the first surface 211 of the circuit build-up substrate with one of its first surface 231 corresponding to such flip-chip bonding pads 213 as shown in FIG. 2B. The chip 23 can be an application processor, in which the first surface 231 is its active surface and a second surface 232 opposite to the first surface 231 is the back one. The first surface 231 of the chip 23 is electrically connected with the flip-chip bonding pads 213 through a plurality of solder balls (conductive bumps or conductive resin, etc.). In the embodiment, the execution sequence of the step S22 and S23 can be interchanged; namely, the conductive pillars 22 can be arranged after the chip 23 is disposed for other embodiments.

It is worth mentioning that the circuit build-up substrate 21 started with the above-mentioned step S21 is a panel type circuit build-up substrate. In traditional wafer fabrication, only the dies or chips formed in a single wafer can be packaged simultaneously, which is time-consuming and has many process limitations. Compared with that, the invention uses a panel type package manufacturing process, in which, as shown in FIG. 2A, the area of the circuit build-up substrate 21 in the invention is multiple times that of a single wafer. Accordingly, the panel type circuit build-up substrate 21 of the invention can carry out the subsequent package of all the dies and chips cut from a plurality of wafers at the same time after the manufacturing process of step S23, thus effectively saving the manufacturing time.

Next, step S24 is to form a molding layer 24 on the first surface 211 of the circuit build-up substrate 21 to cover the conductive pillars 22 and the chip 23 as shown in FIG. 2C. The molding layer 24 is made of insulating materials like novolac-based resin, epoxy-based resin or silicone-based resin. In addition, the molding layer 24 can also be high filler content dielectric material such as a molding compound, which takes the epoxy as the base material with an overall proportion of about 8%-12%, and mingle with fillers accounting for about 70%-90% of the total proportion. Among them, the fillers can be silica and alumina, which will improve mechanical strength, reduce linear thermal expansion coefficient, increase heat conduction and water resistance, and reduce excessive glue.

Step S25 is to grind the top surface of the molding layer 24 as shown in FIG. 2D to expose one first end 221 of each conductive pillar 22 and the second surface 232 of the chip 23. So far, the conductive substrate 27 embedded with the chip 23 and the conductive pillars 22 is formed by the conductive pillars 22, the chip 23 and the molding layer 24.

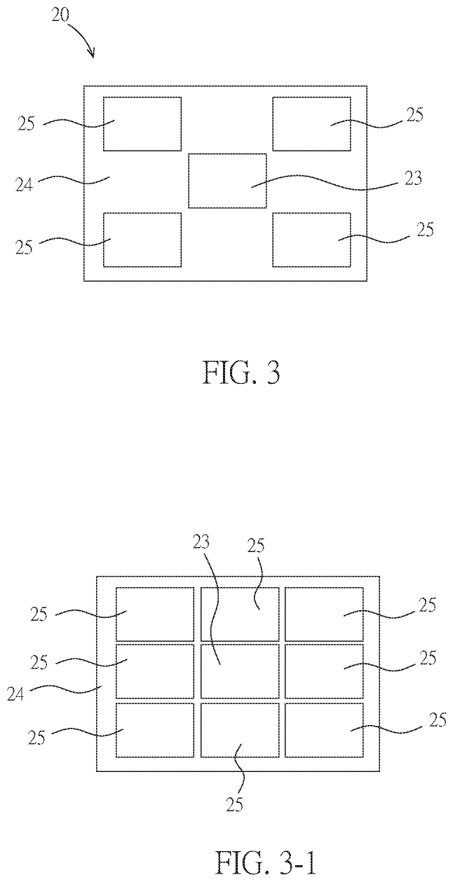

Step S26 is to dispose the memory module 25 on the molding layer 24 as shown in FIG. 2E and electrically connect the memory module to the first end 221 of the corresponding conductive pillars 22 by solder balls (conductive resin or conductive bumps, etc.). Since the conductive pillars 22 is arranged corresponding to the first bonding pads 214 of the circuit build-up substrate 21 and the first bonding pads 214 is located around the flip-chip bonding pads 213, the memory module 25 and the chip 23 will not overlap in an orthographic projection direction D1 as shown in FIG. 3. Accordingly, the chip 23 can be directly exposed for better heat dissipation.

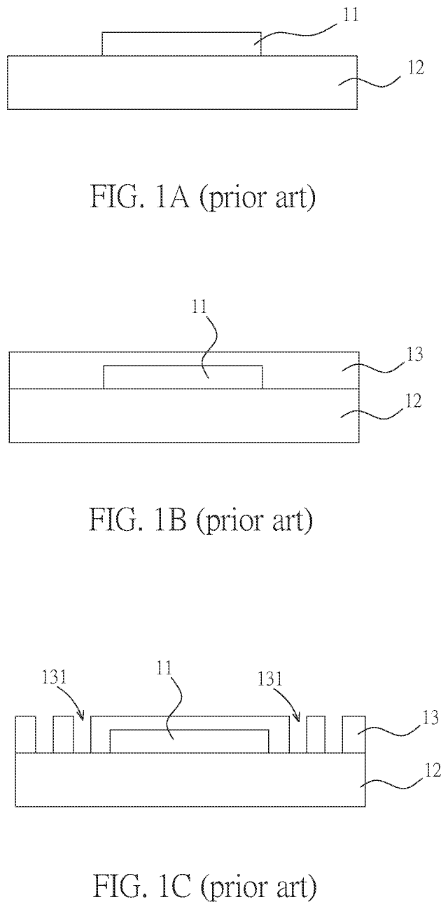

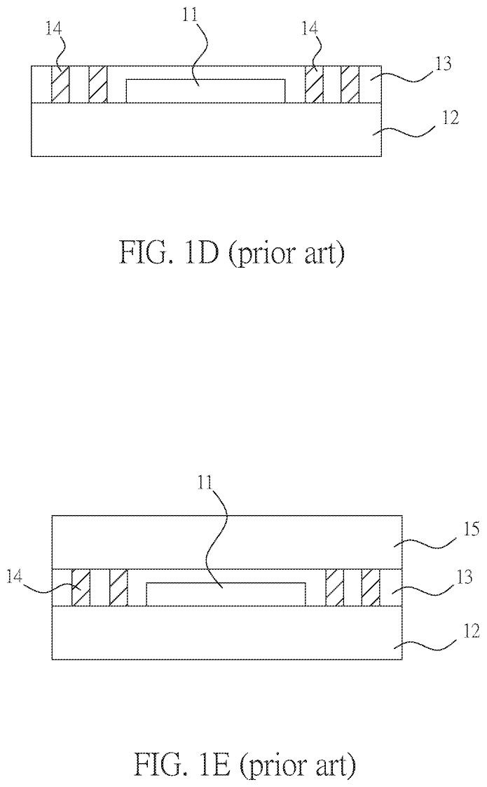

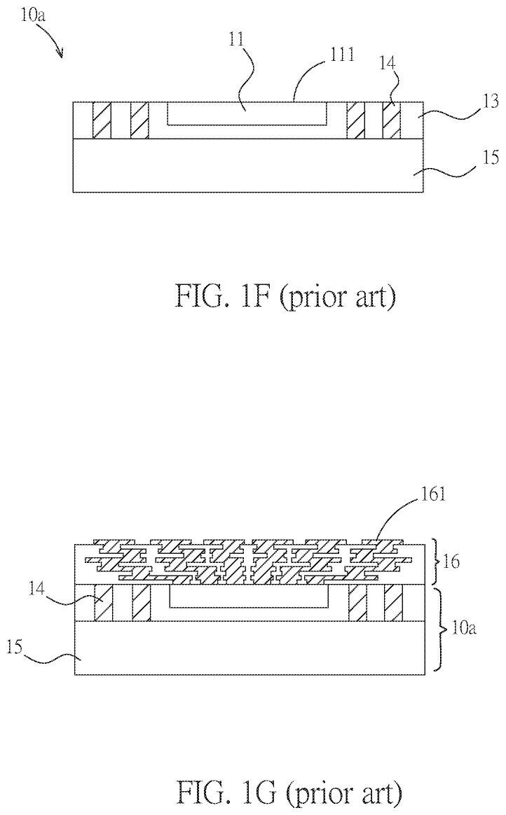

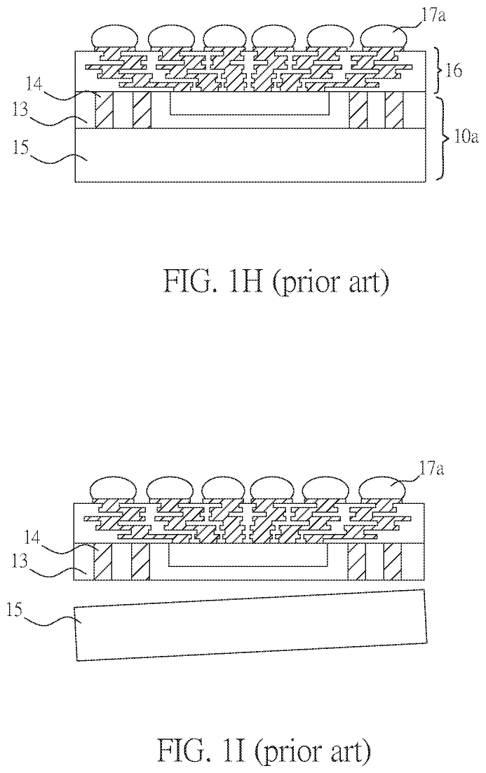

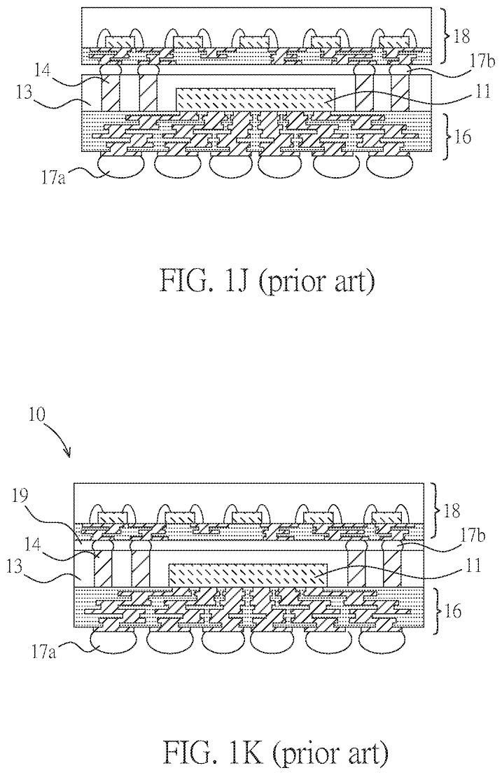

In other embodiments, the memory module 25 can also be configured as shown in FIG. 3-1, in which it is disposed around the chip 23 in the overlooking direction, and does not overlap in the orthographic projection direction Dl. What's more, the configuration of memory module 25 is unrestricted and focuses on the exposure of the chip 23.

Step S27 is to arrange the solder balls (conductive resin or conductive bump, etc.) and electrically connect it to the second bonding pads 215 as shown in FIG. 2E. According to different manufacturing equipment and technology, the step can be carried out simultaneously with that for solder balls disposing in the step S26.

Step S28 is to selectively arrange the heat dissipation components 261, 262 and 263 on the memory module 25 and the second surface 232 of the chip 23 as shown in FIG. 2F to increase the efficiency of the heat dissipation further and complete the semiconductor package structure 20.

From above, the heat dissipation components 261, 262 and 263 are selectively arranged, that is, if the heat dissipation is good enough, no heat dissipation components will be needed.

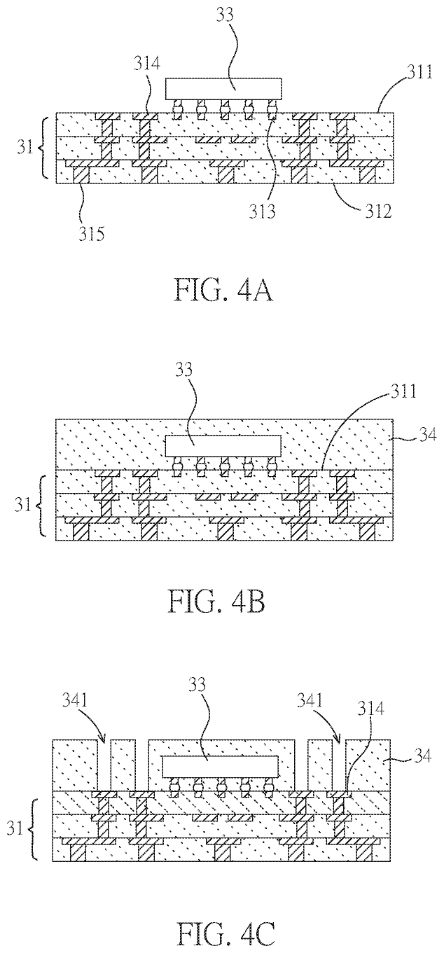

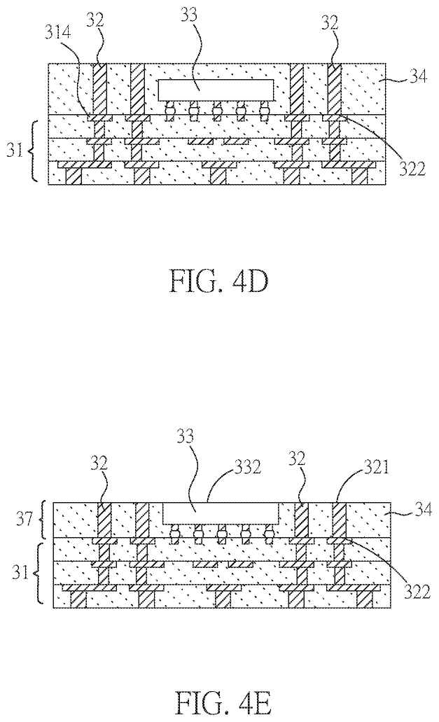

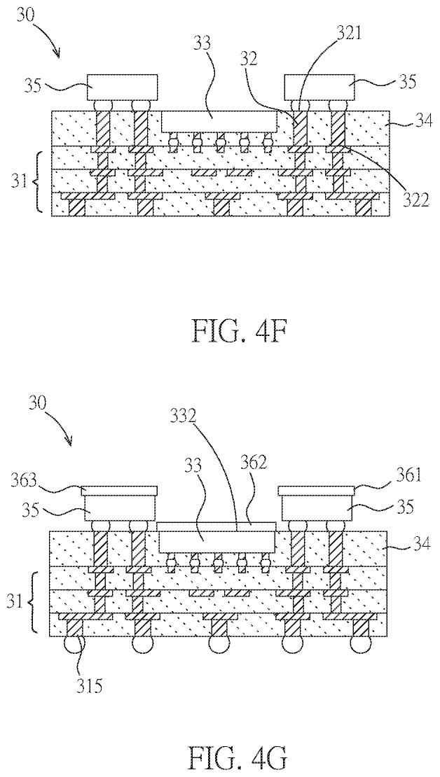

Next, please refer to FIGS. 4A to 4G to illustrate the manufacturing method of the semiconductor package structure 30 of the second embodiment in the invention from steps S31 to S38.

Step S31 is to provide a circuit build-up substrate 31 with a chip 33 arranged on it as shown in FIG. 4A. The circuit build-up substrate 31 has a first surface 311 and a second surface 312, with a plurality of flip-chip bonding pads 313 and a plurality of the first bonding pads 314 exposed on the first surface 311, and a plurality of the second bonding pads 315 exposed on the second surface 312. Among them, the material and structure of the circuit build-up substrate 31 and the chip 33 are the same as that of the circuit build-up substrate 21 and the chip 23 in the first embodiment, which will not be repeated here.

Step S32 is to form a molding layer 24 on the first surface 311 of the circuit build-up substrate 31 as shown in FIG. 4B to cover the chip 33 and the first surface 311 of the circuit build-up substrate 31.

Step S33 is to make a plurality of openings 341 on the molding layer 34 at the position corresponding to the first bonding pads 314 as shown in FIG. 4C by using the laser drilling, mechanical drilling or other drilling techniques.

Step S34 is to fill (or electroplate) metal material into the openings 341 to form a plurality of conductive pillars 32 as shown in FIG. 4D and the second end 322 is electrically connected with the corresponding first bonding pads 314.

Step S35 is to grind the top surface of the molding layer 34 as shown in FIG. 4E to expose the first end 321 of such conductive pillars 32 and the second surface 332 of the chip 33. So far, the conductive substrate 37 embedded with the conductive pillars 32 and the chip 33 is formed by the conductive pillars 32, the chip 33 and the molding layer 34.

Step S36 is to arrange the memory module 35 on the molding layer 34 as shown in FIG. 4F, and electrically connect it to the first end 321 of the corresponding conductive pillars 32 by solder balls (conductive resin or conductive bumps, etc.).

Step S37 is to arrange the solder balls (conductive resin or conductive bump, etc.) and electrically connect it to the second bonding pads 315 as shown in FIG. 4G. According to different manufacturing equipment and technology, the step can be carried out simultaneously with that for solder balls disposing in the step S36.

Step S38 is to selectively arrange the heat dissipation components 361, 362 and 363 on the memory module 35 and the second surface 332 of the chip 33 as shown in FIG. 4G to increase the efficiency of the heat dissipation further and complete the semiconductor package structure 30.

From above, the heat dissipation components 361, 362 and 363 are selectively arranged, that is, if the heat dissipation is good enough, no heat dissipation components will be needed.

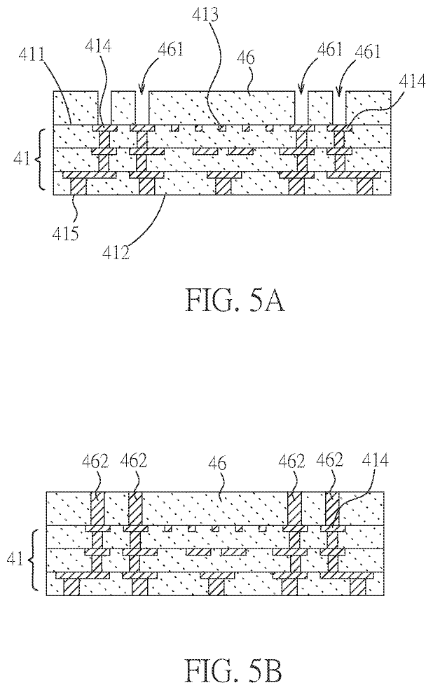

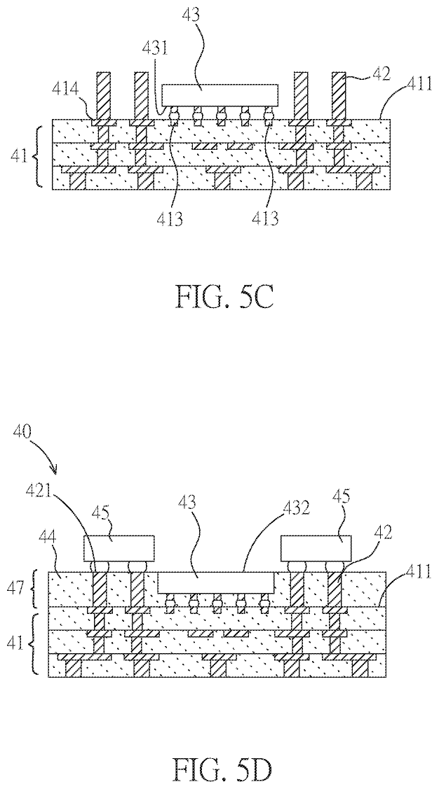

Next, please refer to FIGS. 5A to 5D to illustrate the manufacturing method of the semiconductor package structure 40 of the third embodiment in the invention from steps S41 to S51.

Step S41 is to provide a circuit build-up substrate 41 as shown in FIG. 5A, which has a first surface 411 and a second surface 412, with a plurality of flip-chip bonding pads 413 and a plurality of the first bonding pads 414 exposed on the first surface 411, and a plurality of the second bonding pads 415 on the second surface 412. Among them, such first bonding pads 414 of the circuit build-up substrate 41 are located around such flip-chip bonding pads 413.

Step S42 is to form a patterned photoresistive layer 46 on the first surface 411 of the circuit build-up substrate 41, with a plurality of blind holes 461 formed on it to expose the first bonding pads 414.

Step S43 is to form a metal layer 462 on the exposed first bonding pads 414 as shown in FIG. 5B by using the electroplating process.

Next, please refer to FIG. 5C, step S44 is to remove the patterned photoresistive layer 46 to form a plurality of conductive pillars 42 with such metal layer 462 and expose the flip-chip bonding pads 413.

Step S45 is to arrange the chip 43 on the first surface 411 of the circuit build-up substrate 41 with one of its first surface 431 corresponding to such flip-chip bonding pads 413. The chip 43 can be similar to the chip 23 mentioned above and will not be described here.

Next, please refer to FIG. 5D, step S46 is to form a molding layer 44 on the first surface 411 of the circuit build-up substrate 41 to cover the conductive pillars 42 and the chip 43, and then grind the top surface of the molding layer 44 to expose a first end 421 of each conductive pillars 42 and the second surface 432 of the chip 43. So far, the conductive substrate 47 embedded with the conductive pillars 42 and the chip 43 is formed by the conductive pillars 42, the chip 43 and the molding layer 44.

Step S47 is to arrange the memory module 45 on the molding layer 44 and electrically connect it to the first end 421 of the corresponding conductive pillars 42 by solder balls (conductive resin or conductive bumps, etc.) to form the semiconductor package structure 40 (or selectively arrange the heat dissipation components on the second surface 432 of the chip 43 and/or the memory module 45).

In summary, the semiconductor package structure of the invention has the following characteristics when comparing with the existing technology:

(1) The chip and memory module do not overlap in the projection direction so that the chip can be exposed without being covered by the memory module and other components, which has better heat dissipation.

(2) The second surface of the chip and/or the memory module can be selectively arranged with the heat dissipation components to improve the efficiency of heat dissipation.

(3) The memory module is arranged on the molding layer separately, that is, if part of the memory module is abnormal, only the defective one are to be replaced or reworked without scrapping the whole package, which will save the cost and man-hour accordingly.

(4) Comparing with the InFO package structure and its manufacturing method with die first, the invention features with die last so that it can reduce the burial rate of the chip caused by the process yield of the conductive structure, thus effectively reducing the production cost and improving the product yield.

Even though numerous characteristics and advantages of certain inventive embodiments have been set out in the foregoing description, together with details of the structures and functions of the embodiments, the disclosure is illustrative only. Changes may be made in detail, especially in matters of arrangement of parts, within the principles of the present disclosure to the full extent indicated by the broad general meaning of the terms in which the appended claims are expressed.

What is claimed is:

1. A semiconductor package structure, comprising:
a circuit build-up substrate, which has opposite a first surface and a second surface, with the first surface exposing a plurality of flip-chip bonding pads and a plurality of first bonding pads, and the second surface exposing a plurality of second bonding pads;
a chip, which has opposite a first surface and a second surface, with the former facing the first surface of the circuit build-up substrate and electrically connected to such flip-chip bonding pads;
a plurality of conductive pillars, which has opposite a first end and a second end, with the second end arranged on the first surface of the circuit build-up substrate and electrically connected to the corresponding first bonding pads;
a molding layer, which is arranged on the first surface of the circuit build-up substrate to cover the chip and the conductive pillars, with the second surface of the chip and the first end of the conductive pillars exposed from the molding layer; and
at least a memory module, which is disposed on the molding layer and electrically connected to the first end of the conductive pillars,
wherein the chip and the memory module do not overlap in an orthographic projection direction.

2. The semiconductor package structure of claim 1, further comprising:
a conductive adhesive layer, which is arranged between the conductive pillars and the first bonding pads.

3. The semiconductor package structure of claim 1, further comprising:
a heat dissipation component, which is disposed on the memory module and/or on the second surface of the chip.

4. The semiconductor package structure of claim 1, wherein the circuit build-up substrate has at least one circuit build-up structure that has a conductor layer, a conductive pillars layer and a dielectric layer, with the conductor layer and the conductive pillars layer overlapping each other and embedded in the dielectric layer.

5. The semiconductor package structure of claim 1, wherein the first bonding pads of the circuit build-up substrate are located around the flip-chip bonding pads.

6. A manufacturing method for a semiconductor package structure, comprising:
providing a circuit build-up substrate, which has a first surface that exposes a plurality of flip-chip bonding pads and a plurality of first bonding pads located around the flip-chip bonding pads;
forming a conductive substrate embedded with a chip and a plurality of conductive pillars on the first surface of the circuit build-up substrate, in which the first surface the chip is disposed corresponding to the flip-chip bonding pads and the second end of the conductive pillars is disposed corresponding to the first bonding pads, wherein a second surface of the chip and a first end of each conductive pillars are exposed from an upper surface of the conductive substrates; and
arranging at least one memory module on the conductive substrate, corresponding to the first end of the conductive pillars, wherein the memory module and the chip do not overlap in an orthographic projection direction.

7. The manufacturing method of claim 6, wherein the step of forming the conductive substrate embedded with a chip and the conductive pillars, comprising:
arranging the conductive pillars on the first surface of the circuit build-up substrate with its second end corresponding to the first bonding pads;
disposing the chip on the first surface of the circuit build-up substrate with its first surface corresponding to such flip-chip bonding pads; and
forming a molding layer on the first surface of the circuit build-up substrate to cover the conductive pillars and chips and expose the first end of each conductive pillars and the second surface of the chip.

8. The manufacturing method of claim 7, wherein each conductive pillar is electrically connected to the corresponding first bonding pads by a conductive adhesive layer at the second end.

9. The manufacturing method of claim 7, wherein the step of arranging the conductive pillars, further comprising:
forming a patterned photoresistive layer on the first surface of the circuit build-up substrate and a plurality of blind holes to expose the first bonding pads;
forming a metal layer on the blind holes and exposing from the first bonding pads; and
removing the patterned photoresistive layer to form the conductive pillars and expose the flip-chip bonding pads.

10. The manufacturing method of claim 6, wherein the step of forming the conductive substrate embedded with the chip and the conductive pillars, comprising:
disposing the chip on the first surface of the circuit build-up substrate with its first surface corresponding to the flip-chip bonding pads;
forming a molding layer on the first surface of the circuit build-up substrate to cover the chip;
forming a plurality of openings on the molding layer which are corresponding to the first bonding pads;
forming a plurality of conductive pillars in the openings that are electrically connected to the corresponding first bonding pads; and
exposing the first end of each conductive pillar and the second surface of the chip from the molding layer.

11. The manufacturing method of claim 6, further comprising:
disposing a heat dissipation component on the second surface of the chip and/or on the memory module.
